(19) United States
(12) Patent Application Publication
(10) Pub. No.: US 2026/0024593 A1
(43) Pub. Date: Jan. 22, 2026

(54) STORAGE DEVICE CHANGING ADDRESS, METHOD OF OPERATING THE SAME, AND METHOD OF OPERATING ELECTRONIC DEVICE INCLUDING THE SAME

(71) Applicant: SAMSUNG ELECTRONICS CO., LTD., Suwon-si (KR)

(72) Inventor: Jong Heon JEONG, Suwon-si (KR)

(73) Assignee: SAMSUNG ELECTRONICS CO., LTD., Suwon-si (KR)

(21) Appl. No.: 19/188,791

(22) Filed: Apr. 24, 2025

(30) Foreign Application Priority Data
Jul. 22, 2024 (KR) 10-2024-0096348

(51) Int. Cl. G11C 16/30; G11C 16/08; G11C 16/26

(52) U.S. Cl. CPC G11C 16/30; G11C 16/08; G11C 16/26

(57) ABSTRACT

A method of operating a storage device includes receiving a second power supply voltage among a first power supply voltage and the second power supply voltage from a host device, driving a logic circuit and an internal memory device of the storage device, based on the second power supply voltage, changing an input address of the internal memory device from a first address to a second address, receiving a first read request corresponding to the first address from the host device, providing a negative acknowledge response to the host device based on the first read request, after providing the negative acknowledge response, receiving a second read request corresponding to the second address from the host device, providing a positive acknowledge response to the host device based on the second read request, and after providing the positive acknowledge response, receiving the first power supply voltage from the host device.

### CROSS-REFERENCE TO RELATED APPLICATION

This application claims priority under 35 U.S.C. § 119 to Korean Patent Application No. 10-2024-0096348 filed on Jul. 22, 2024, in the Korean Intellectual Property Office, the disclosure of which being incorporated by reference herein in its entirety.

### BACKGROUND

Methods, apparatuses and devices consistent with the present disclosure relate to a storage device, and more particularly, to a storage device changing an address, a method of operating the same, and a method of operating an electronic device including the same.

A memory device stores data in response to a write request and outputs data stored therein in response to a read request. For example, the memory device is classified as a volatile memory device, which loses data stored therein when a power is turned off, such as a dynamic random access memory (DRAM) device or a static RAM (SRAM) device, or a non-volatile memory device, which retains data stored therein even when a power is turned off, such as a flash memory device, a phase-change RAM (PRAM), a magnetic RAM (MRAM), or a resistive RAM (RRAM).

The non-volatile memory device may be used in a storage device storing a large amount of data. The storage device may support a normal mode and a low power mode (i.e., a low-power mode). Most of function blocks of the storage device may be deactivated in the low power mode. There may be required a technique which allows the storage device to stably escape from the low power mode in the above condition.

### SUMMARY

It is an aspect to provide a storage device changing an address, a method of operating the same, and a method of operating an electronic device including the same.

According to an aspect of one or more embodiments, there is provided a method of operating a storage device, the method comprising receiving a second power supply voltage among a first power supply voltage and the second power supply voltage from a host device; driving a logic circuit and an internal memory device of the storage device, based on the second power supply voltage; changing, by the logic circuit, an input address of the internal memory device from a first address to a second address; receiving, by the internal memory device, a first read request corresponding to the first address from the host device; providing, by the internal memory device, a negative acknowledge response to the host device based on the first read request; after providing the negative acknowledge response, receiving, by the internal memory device, a second read request corresponding to the second address from the host device; providing, by the internal memory device, a positive acknowledge response to the host device based on the second read request; and after providing the positive acknowledge response, receiving the first power supply voltage from the host device.

According to another aspect of one or more embodiments, there is provided a storage device comprising a logic circuit; an internal memory device; and a power supply circuit. The power supply circuit is configured to independently receive a first power supply voltage and a second power supply voltage from a host device, support a first power mode in which both the first power supply voltage and the second power supply voltage are used, support a second power mode in which only the second power supply voltage is used, and drive the logic circuit and the internal memory device, based on the second power supply voltage. The logic circuit is configured to trigger a wake-up event for exiting the second power mode; and change an input address of the internal memory device from a first address to a second address based on the wake-up event that is triggered. The internal memory device is configured to receive a read request from the host device; provide a positive acknowledge response to the host device in response to an address that corresponds to the read request coinciding with the input address; and provide a negative acknowledge response to the host device in response to the address that corresponds to the read request not coinciding with the input address.

According to yet another aspect of one or more embodiments, there is provided a method of operating an electronic device which includes a host device and a storage device, the method comprising providing, by the host device, a second power supply voltage among a first power supply voltage and the second power supply voltage to the storage device; driving, by the storage device, a logic circuit and an internal memory device of the storage device based on the second power supply voltage; changing, by the logic circuit, an input address of the internal memory device from a first address to a second address; providing, by the host device, a first read request corresponding to the first address to the internal memory device; providing, by the internal memory device, a negative acknowledge response to the host device based on the first read request; providing, by the host device, a second read request corresponding to the second address to the internal memory device, based on the negative acknowledge response; providing, by the internal memory device, a positive acknowledge response to the host device based on the second read request; and providing, by the host device, the first power supply voltage to the storage device based on the positive acknowledge response.

### BRIEF DESCRIPTION OF THE FIGURES

The above and other aspects will become apparent by describing in detail embodiments thereof with reference to the accompanying drawings, in which:

FIG. 1 is a block diagram of an electronic device according to an embodiment;

FIG. 2 is a diagram describing power supply management of a related art electronic device;

FIG. 3 is a graph describing signals and operation states of the power supply management of the related art electronic device of FIG. 2;

FIG. 4 is a diagram describing power management of an electronic device according to some embodiments;

FIG. 5 is a flowchart describing a method of operating an electronic device according to some embodiments;

FIG. 6 is a block diagram of an electronic device according to some embodiments;

FIG. 7 is a diagram describing a method of operating an electronic device according to some embodiments;

FIG. 8 is a block diagram of a storage device according to some embodiments;

FIG. 9 is a diagram describing a data signal according to some embodiments;

FIG. 10A is a diagram describing a data signal and a clock signal according to

some embodiments;

FIG. 10B is a diagram describing a data signal and a clock signal according to some embodiments;

FIG. 10C is a diagram describing a data signal and a clock signal according to some embodiments;

FIG. 11 is a diagram describing period information according to some embodiments;

FIG. 12 is a block diagram of an electronic device according to some embodiments;

FIG. 13 is a flowchart describing a method of operating an electronic device according to some embodiments; and

FIG. 14 is a flowchart describing a method of operating a storage device according to some embodiments.

### DETAILED DESCRIPTION

Below, various embodiments will be described in detail and clearly to such an extent that one skilled in the art carries out embodiments of the present disclosure easily.

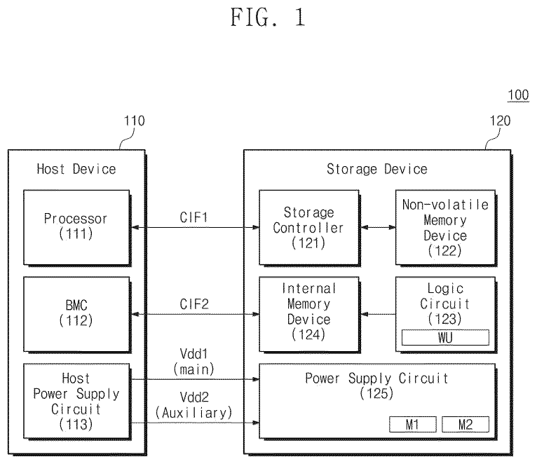

FIG. 1 is a block diagram of an electronic device according to an embodiment. Referring to FIG. 1, an electronic device 100 may manage various information to be provided to the user, such as an image, a video, a text, and voice. For example, in some embodiments, the electronic device 100 may be implemented with a computing system, which is configured to process various information, such as a personal computer (PC), a laptop computer, a server, a workstation, a tablet PC, a smartphone, a digital camera, and/or a black box. In some embodiments, the electronic device 100 may be implemented with a storage system, a server system, a database server, etc. for managing a large amount of user data.

The electronic device 100 may include a host device 110 and a storage device 120. The host device 110 may control all the operations of the electronic device 100. For example, the host device 110 may store data in the storage device 120, may read data stored in the storage device 120, or may delete data stored in the storage device 120. The host device 110 may include a processor 111, a baseboard management controller (BMC) 112, and a host power supply circuit 113.

The processor 111 may store data in the storage device 120. For example, in an embodiment, the processor 111 may be implemented with a central processing unit (CPU). The processor 111 may execute an operating system (OS) and may manage data of the storage device 120 through the executed offset signal (OS). The processor 111 may communicate with the storage device 120 through a first communication interface circuit CIF1. For example, in an embodiment, the first communication interface circuit CIF1 may be implemented with a peripheral component interconnect express (PCIe) interface circuit. In an embodiment, the first communication interface circuit CIF1 may support in-band communication.

The BMC 112 may manage hardware information of the storage device 120. For example, the BMC 112 may receive the hardware information from the storage device 120 and may manage a source associated with a physical environment (e.g., a voltage, a current, or a maximum data bandwidth) of the storage device 120 based on the hardware information. The BMC 112 may operate independently of the operating system (OS) of the processor 111. The BMC 112 may communicate with the storage device 120 through a second communication interface circuit CIF2. For example, in an embodiment, the second communication interface circuit CIF2 may be implemented with a system management bus (SM Bus) interface circuit. In an embodiment, the second communication interface circuit CIF2 may support out-of-band communication.

In some embodiments, the out-of-band communication may be implemented based on at least one of various kinds of protocols such as an open computer project (OCP) standard, a platform level data model (PLDM) standard, a network controller sideband interface (NC-SI) standard, a Redfish standard, a non-volatile memory express management interface (NVMe_MI) standard, and/or a management component transport protocol (MCTP) standard.

The host power supply circuit 113 may independently provide a first power supply voltage Vdd1 and a second power supply circuit Vdd2 to the storage device 120. The first power supply voltage Vdd1 may be referred to as a “main power supply voltage”. The second power supply voltage Vdd2 may be referred to as an “auxiliary power supply voltage”. In an embodiment, the auxiliary power supply voltage may be lower than the main power supply voltage. In an embodiment, the auxiliary power supply voltage may be a constant power supply voltage.

For example, the first power supply voltage Vdd1 may be used for a first power mode M1 of the storage device 120. The second power supply voltage Vdd2 may be used for both the first power mode M1 and a second power mode M2 of the storage device 120. The first power mode M1 may be referred to as a “normal mode”. The second power mode M2 may be referred to as a “low power mode (i.e., low-power mode)” or an “extreme low power mode”.

In some embodiments, the first power mode M1 may correspond to an L0 link state defined by the PCIe standard, and the second power mode M2 may correspond to an L2 link state defined by the PCIe standard. However, embodiments are not limited thereto.

The storage device 120 may include a storage controller 121, a non-volatile memory device 122, a logic circuit 123, an internal memory device 124, and a power supply circuit 125. The storage controller 121, the non-volatile memory device 122, the logic circuit 123, the internal memory device 124, and the power supply circuit 125 may be referred to as “components”.

The storage controller 121 may control all the operations of the storage device 120 under control of the processor 111. For example, under control of the processor 111, the storage controller 121 may store data in the non-volatile memory device 122, may read the stored data, or may delete the stored data. The storage controller 121 may communicate with the processor 111 through the first communication interface circuit CIF1.

The non-volatile memory device 122 may store data under control of the storage controller 121. In some embodiments, the non-volatile memory device 122 may be a NAND flash memory device, but embodiments are not limited thereto. For example, in some embodiments, the non-volatile memory device 122 may be one of various storage devices, which retain data stored therein even when a power is turned off, such as a phase-change random access memory (PRAM), a magnetic random access memory (MRAM), a resistive random access memory (RRAM), and/or a ferroelectric random access memory (FRAM).

The logic circuit 123 may manage a wake-up event WU. The wake-up event WU may indicate to change a power mode of the storage device 120 from the second power mode M2 to the first power mode M1. For example, the logic circuit 123 may trigger the wake-up event WU and may control the internal memory device 124 based on the triggered wake-up event WU.

The internal memory device 124 may store the hardware information. The internal memory device 124 may communicate with the BMC 112 through the second communication interface circuit CIF2. For example, in an embodiment, the internal memory device 124 may be implemented with an electrically erasable programmable read-only memory (EEPROM). The hardware information stored in the internal memory device 124 may be referred to as “field replaceable unit (FRU) information” or “vital product data (VPD) information”.

The power supply circuit 125 may independently receive the first power supply voltage Vdd1 and the second power supply circuit Vdd2 from the host device 110. The power supply circuit 125 may support the first power mode M1 in which both the first power supply voltage Vdd1 and the second power supply voltage Vdd2 are used. The power supply circuit 125 may support the second power mode M2 in which the second power supply voltage Vdd2 is used. In some embodiments, the power supply circuit 125 may support the second power mode M2 in which only the second power supply voltage Vdd2 is used.

In the first power mode M1, most or all of the components of the storage device 120 may be activated. In the second power mode M2, most of the components of the storage device 120 may be deactivated, and the logic circuit 123 and the internal memory device 124 may be activated. That is, in the second power mode M2, the power supply circuit 125 may drive the logic circuit 123 and the internal memory device 124 based on the second power supply voltage Vdd2.

According to various embodiments, in the second power mode M2, the storage device 120 may provide an intention to exit the second power mode M2 to the host device 110 by changing an input address of the internal memory device 124 through the logic circuit 123. The input address may be referred to as a “slave address”. In other words, in some embodiments, in the second power mode M2, the storage device 120 may provide the intention to exit the second power mode M2 to the host device 110 indirectly by changing the input address of the internal memory device 124 through the logic circuit 123.

In detail, because most components are deactivated during the second power mode M2, it may be difficult for the storage device 120 to provide the intention to exit the second power mode M2 to the host device 110. During the second power mode M2, the first communication interface circuit CIF1 may be deactivated, and the second communication interface circuit CIF2 may be activated. During the second power mode M2, the host device 110 may provide a read request to the internal memory device 124 through the second communication interface circuit CIF2.

The internal memory device 124 may have the input address. In response to the read request having an address coinciding with the input address, the internal memory device 124 may return an acknowledge response to the host device 110. In an embodiment, the internal memory device 124 may return a positive acknowledge response based on the internal memory device 124 having the input address that coincides with the address indicated in the read request. In an embodiment, in response to the read request having an address different from the input address, the internal memory device 124 may return a negative acknowledge response to the host device 110.

In an embodiment, when the wake-up event WU is triggered by the logic circuit 123, the logic circuit 123 may change the input address of the internal memory device 124 to be different from a default address. In an embodiment, based on the negative acknowledge response being returned from the storage device 120 as a response to the read request corresponding to the default address, the host device 110 may detect the intention for the storage device 120 to exit the second power mode M2.

Afterwards, the host device 110 may provide the first power supply voltage Vdd1 to the storage device 120. The storage device 120 may operate in the first power mode M1 based on the first power supply voltage Vdd1.

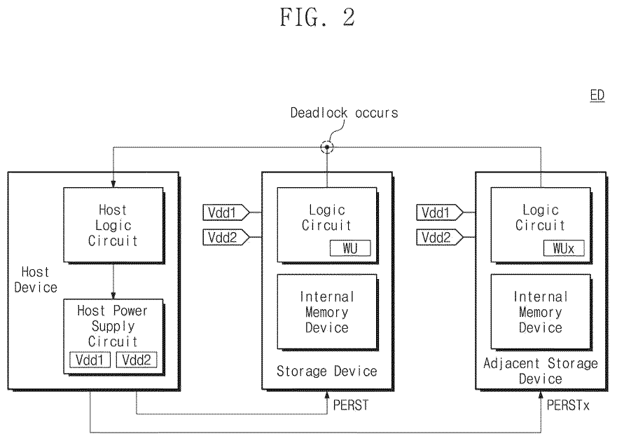

FIG. 2 is a diagram describing power supply management of a related art electronic device. Referring to FIG. 2, a related art electronic device ED may include a host device, a storage device, and an adjacent storage device. The host device may manage the storage device and the adjacent storage device. The adjacent storage device may be adjacent to the storage device.

For better understanding of the present disclosure, the related art electronic device ED will be described, but the related art electronic device ED may include features not disclosed in documents of the information disclosure statement and is not intended to limit the scope and spirit of the embodiments described herein.

The host device may include a host logic circuit and a host power supply circuit. The host logic circuit may receive an electrical signal corresponding to the wake-up event WU from the storage device. The host logic circuit may receive an electrical signal corresponding to a wake-up event WUx from the adjacent storage device. The host logic circuit may control the host power supply circuit to independently provide the first power supply voltage Vdd1 and the second power supply circuit Vdd2 to the adjacent storage device.

The host device may provide a signal PERST to the storage device, based on the electrical signal corresponding to the wake-up event WU. The signal PERST may be a fundamental reset signal defined by the PCIe standard. For example, after the first power supply voltage Vdd1 is supplied, the storage device may sequentially activate function blocks of the storage device based on the signal PERST. The host device may provide a signal PERSTx to the adjacent storage device, based on the electrical signal corresponding to the wake-up event WUx. The signal PERSTx may be a fundamental reset signal defined by the PCIe standard.

The storage device may be driven based on the first power supply voltage Vdd1 and the second power supply voltage Vdd2. The storage device may support the first power mode M1 in which all the first and second power supply voltages Vdd1 and Vdd2 are used. The storage device may support the second power mode M2 in which the second power supply voltage Vdd2 is used. The storage device may include a logic circuit and an internal memory device.

In the related art electronic device, when the wake-up event WU is triggered, the logic circuit may change the electrical signal to be provided to the host logic circuit from a logic high level to a logic low level. Thus, the host logic circuit may directly detect the wake-up event WU according to the logic level change. The host logic circuit may direct the host power supply circuit to again supply the first power supply voltage Vdd1, in response to that the voltage level of the electrical signal is changed.

The adjacent storage device may be driven based on the first and second power supply voltages Vdd1 and Vdd2. The adjacent storage device may support the first power mode M1 and the second power mode M2. The adjacent storage device may include a logic circuit and an internal memory device. When the wake-up event WUx is triggered, the logic circuit may change the electrical signal to be provided to the host logic circuit from the logic high level to the logic low level.

The related art electronic device ED may be vulnerable to a deadlock. For example, the host logic circuit may include an input transistor. A drain node of the input transistor may receive the electrical signal corresponding to the wake-up event WU from the storage device and may receive the electrical signal corresponding to the wake-up event WUx from the adjacent storage device.

When the wake-up events WU and WUx are simultaneously caused by the storage device and the adjacent storage device or are continuously caused within a short time, it may be difficult for the host logic circuit to determine whether the change in the voltage level of the electrical signal corresponds to the storage device or the adjacent storage device. In this case, the host logic circuit may miss providing the signal PERST or providing the signal PERSTx. The storage device or the adjacent storage device may be incapable of activating the function blocks and may be deadlocked.

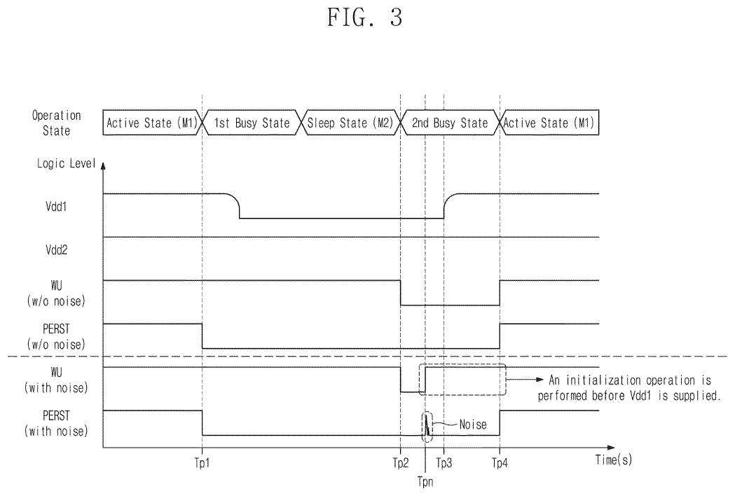

FIG. 3 is a graph describing signals and operation states of the related art electronic device of FIG. 2. Referring to FIGS. 2 and 3, the related art electronic device ED may include the storage device and the host device. The storage device may support the first power mode M1 and the second power mode M2. The storage device may receive the first power supply voltage Vdd1 and the second power supply voltage Vdd2 from the host device. The storage device may provide the electrical signal corresponding to the wake-up event WU to the host device. The storage device may receive the signal PERST from the host device.

Referring to the graph of FIG. 3, the horizontal axis represents a time, and the vertical axis represents an operation state or a logic level. The wake-up event WU and the signal PERST will be individually described in association with the case there is noise during a second busy state and the case where there is no noise during the second busy state.

Before a first time point Tp1, the storage device may operate in an active state. The active state may correspond to the first power mode M1. In the active state, the storage device may receive the first power supply voltage Vdd1 and the second power supply voltage Vdd2 from the host device. The electrical signal corresponding to the wake-up event WU may have the logic high level as a default value. The signal PERST may have the logic high level as a default value.

At the first time point Tp1, the storage device may enter a first busy state for the change from the first power mode M1 to the second power mode M2. The host device may change the signal PERST from the logic high level to the logic low level.

During the first busy state, the first power supply voltage Vdd1 which is provided from the host device may be blocked. The second power supply voltage Vdd2 may be continuously supplied from the host device. The electrical signal corresponding to the wake-up event WU may maintain the logic high level. The signal PERST may maintain the logic low level. After the function blocks of the storage device using the first power supply voltage Vdd1 are deactivated, the storage device may enter a sleep state. The sleep state may correspond to the second power mode M2.

During the sleep state, the first power supply voltage Vdd1 may maintain a blocked state. The second power supply voltage Vdd2 may be continuously supplied from the host device. The electrical signal corresponding to the wake-up event WU may maintain the logic high level. The signal PERST may maintain the logic low level.

At a second time point Tp2, the storage device may trigger the wake-up event WU. The storage device may change the electrical signal corresponding to the wake-up event WU from the logic high level to the logic low level. Immediately after the second time point Tp2, the storage device may enter the second busy state for the change from the second power mode M2 to the first power mode M1.

A noise event time point Tpn may indicate an example of a point in time when the noise of the signal PERST occurs. When there is no noise, during the second busy state, the signal PERST may maintain the logic low level, and the electrical signal corresponding to the wake-up event WU maintain the logic low level.

In contrast, when the noise occurs, the signal PERST may temporarily have the logic high level due to the noise. The storage device may change the electrical signal corresponding to the wake-up event WU to the logic high level in response to the noise. The host device may abnormally recognize that the storage device is in a state of performing an initialization operation, based on the changed electrical signal. The initialization operation may refer to an operation of activating the function blocks of the storage device and setting operation conditions of the function blocks.

The noise event time point Tpn may be earlier than a third time point Tp3 at which the first power supply voltage Vdd1 is again supplied. The host device and the storage device may abnormally perform the initialization operation in an environment in which the first power supply voltage Vdd1 is not supplied. Due to the abnormally performed initialization operation, the function blocks of the storage device may be incapable of being activated or may be unstably activated.

At a fourth time point Tp4, the storage device may again enter the active state. The host device may change the signal PERST from the logic low level to the logic high level. When there is no noise, at the fourth time point Tp4 following the third time point Tp3 at which the first power supply voltage Vdd1 is stably supplied, the storage device may change the electrical signal corresponding to the wake-up event WU to the logic high level. The host device and the storage device may perform the initialization operation in an environment in which the first power supply voltage Vdd1 is supplied. Through the initialization operation, the function blocks of the storage device may be normally activated. The storage device may stably operate in the active state.

In contrast, when the noise occurs at the noise event time point Tpn, the storage device may unstably perform the initialization operation in an environment in which the first power supply voltage Vdd1 is not supplied. In this case, even though the storage device enters the active state, the storage device may be incapable of normally operating. Accordingly, the related art electronic device ED may be vulnerable to the noise of the signal PERST. The change of the power mode of the related art electronic device ED may become unstable.

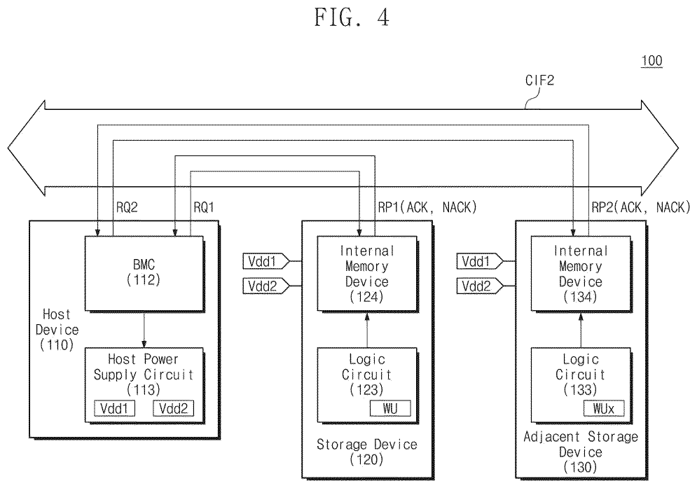

FIG. 4 is a diagram describing power management of an electronic device according to some embodiments. Referring to FIG. 4, the electronic device 100 may include the host device 110, the storage device 120, an adjacent storage device 130, and the second communication interface circuit CIF2. In an embodiment, the second communication interface circuit CIF2 may be always driven by the second power supply voltage Vdd2. The second communication interface circuit CIF2 may support the out-of-band communication between the BM C112, the internal memory device 124, and an internal memory device 134.

The host device 110 may include the BMC112 and the power host supply circuit 113. The host power supply circuit 113 may provide the first and second power supply voltages Vdd1 and Vdd2 to the storage device 120 and the adjacent storage device 130, independently.

The storage device 120 may include the logic circuit 123 and the internal memory device 124. The logic circuit 123 may manage the wake-up event WU. When the logic circuit 123 triggers the wake-up event WU, the logic circuit 123 may change the input address of the internal memory device 124.

The adjacent storage device 130 may include a logic circuit 133 and the internal memory device 134. The logic circuit 133 may manage the wake-up event WUx. When the logic circuit 133 triggers the wake-up event WUx, the logic circuit 133 may change the input address of the internal memory device 134.

According to various embodiments, to detect an exit intention of the storage device 120 to exit the second power mode M2 (e.g., the intention for the change from the second power mode M2 to the first power mode M1, which is described with reference to FIG. 1) and an exit intention of the adjacent storage device 130, the host device 110 may perform the read operations of the internal memory device 124 and the internal memory device 134 through the BMC 112.

In detail, the BMC 112 may provide a read request RQ1 to the internal memory device 124 through the second communication interface circuit CIF2. When the input address is not changed by the logic circuit 123, the internal memory device 124 may return a response RP1 including a positive acknowledge response ACK to the BMC 112 through the second communication interface circuit CIF2.

In contrast, when the logic circuit 123 changes the input address of the internal memory device 124 based on the wake-up event WU, the internal memory device 124 may return the response RP1 including a negative acknowledge response NACK to the BMC 112 through the second communication interface circuit CIF2. The BMC 112 may accurately detect the exit intention of the storage device 120 by performing an additional read request for the changed address based on the negative acknowledge response NACK.

Likewise, the BMC 112 may provide a read request RQ2 to the internal memory device 134 through the second communication interface circuit CIF2. When the input address is not changed by the logic circuit 133, the internal memory device 134 may return a response RP2 including the positive acknowledge response ACK to the BMC 112 through the second communication interface circuit CIF2.

In contrast, when the logic circuit 133 changes the input address of the internal memory device 134 based on the wake-up event WUx, the internal memory device 134 may return the response RP2 including the negative acknowledge response NACK to the BMC 112 through the second communication interface circuit CIF2. The BMC 112 may accurately detect the exit intention of the adjacent storage device 130 by performing an additional read request for the changed address based on the negative acknowledge response NACK.

As described above, according to various embodiments, because a logic circuit of a storage device may express the exit intention by changing an input address of an internal memory device of the storage device instead of directly transmitting an electrical signal to a host device, the deadlock due to the conflict between electrical signals of logic circuits in an electronic device may be suppressed.

The host device may detect the exit intention of the storage device through a method similar to a method of reading the stored data. Because the read method is performed based on a data signal and a clock signal designed relatively complicatedly, the read method may be more robust to noise as compared to the related art method of transmitting a two-level electrical signal.

The host device may stably detect the exit intention of the storage device by performing the read operation of the internal memory device which is always activated regardless of the power mode, and thus, the complicated change of the design of the host device may not be required.

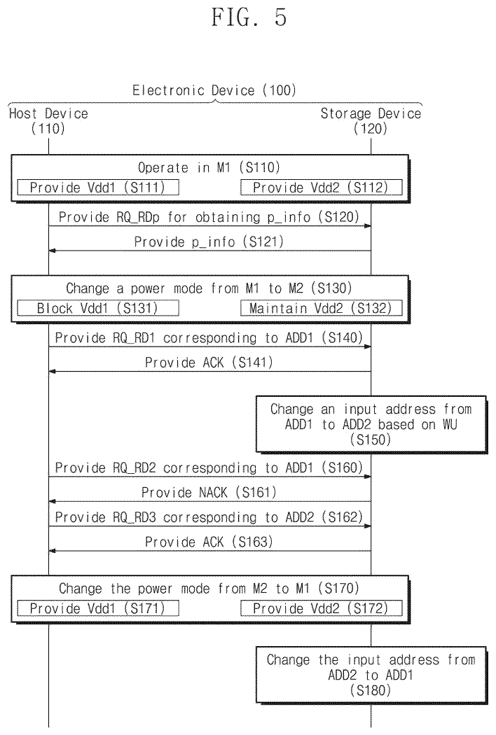

FIG. 5 is a flowchart describing a method of operating an electronic device according to some embodiments. Referring to FIG. 5, the electronic device 100 may include the host device 110 and the storage device 120.

In operation S110, the electronic device 100 may operate the storage device 120 in the first power mode M1. The first power mode M1 may use both the first power supply voltage Vdd1 and the second power supply voltage Vdd2.

In an embodiment, operation S110 may include operation S111 and operation S112. In operation S111, the host device 110 may provide the first power supply voltage Vdd1 to the storage device 120. In operation S112, the host device 110 may provide the second power supply voltage Vdd2 to the storage device 120.

In operation S120, the host device 110 may provide a read request RQ_RDp to the storage device 120 to obtain period information p_info. The period information p_info may be stored in an internal memory device of the storage device 120 as FRU information. The period information p_info may include information which defines a time period where the read operation of the internal memory device of the storage device 120 is performed by the host device 110.

In operation S121, the storage device 120 may provide the period information p_info to the host device 110 based on the read request RQ_RDp. The host device 110 may set the time period of the read operation to be performed on the internal memory device of the storage device 120, based on the period information p_info.

In some embodiments, operation S120 and operation S121 may be performed during the first power mode M1.

In operation S130, the electronic device 100 may change the power mode of the storage device 120 from the first power mode M1 to the second power mode M2. The second power mode M2 may use only the second power supply voltage Vdd2 among the first and second power supply voltages Vdd1 and Vdd2.

In an embodiment, operation S130 may include operation S131 and operation S132. In operation S131, the host device 110 may stop the first power supply voltage Vdd1 from being provided to the storage device 120. The host device 110 may maintain the second power supply voltage Vdd2 being provided to the storage device 120. The storage device 120 may operate in the second power mode M2.

In operation S140, the host device 110 may provide a first read request RQ_RD1 corresponding to a first address ADD1 to the storage device 120. The first address ADD1 may be a default address of the internal memory device of the storage device 120. Before the wake-up event WU occurs, the input address of the internal memory device may be the first address ADD1.

In operation S141, the storage device 120 may provide the acknowledge response ACK to the host device 110 based on the first read request RQ_RD1. For example, the storage device 120 may return the positive acknowledge response ACK to the host device 110 in response to the first address ADD1 corresponding to the first read request RQ_RD1 coinciding with the input address.

In an embodiment, operation S140 and operation S141 may be repeated depending on the time period of the period information p_info, until the wake-up event WU occurs. In an embodiment, operation S140 and operation S141 may be repeated periodically based on the time period.

In operation S150, the storage device 120 may trigger the wake-up event WU. The storage device 120 may change the input address of the internal memory device of the storage device 120 from the first address ADD1 to a second address ADD2, based on the wake-up event WU. That is, the input address of the internal memory device may be set to the second address ADD2. That the input address is set to the second address ADD2 may indicate the intention to exit the second power mode M2.

In operation S160, the host device 110 may provide a second read request RQ_RD2 corresponding to the first address AD1 to the storage device 120. The time period between the first read request RQ_RD1 and the second read request RQ_RD2 may be set based on the period information p_info.

In operation S161, the storage device 120 may provide the negative acknowledge response NACK to the host device 110 based on the second read request RQ_RD2. For example, the storage device 120 may return the negative acknowledge response

NACK to the host device 110, in response to the first address ADD1 corresponding to the second read request RQ_RD2 not coinciding with the input address (i.e., the second address ADD2) set in operation S150. In an embodiment, the negative acknowledgement response NACK may include information indicating the second address ADD2.

In operation S162, the host device 110 may provide a third read request RQ_RD3 corresponding to the second address ADD2 to the storage device 120, based on the negative acknowledge response NACK. The time period between the second read request RQ_RD2 and the third read request RQ_RD3 may be set based on the period information p_info.

In operation S163, the storage device 120 may provide the acknowledge response A CK to the host device 110 based on the third read request RQ_RD3. For example, the storage device 120 may return the acknowledge response ACK to the host device 110, in response to the second address ADD2 corresponding to the third read request RQ_RD3 coinciding with the input address (i.e., the second address ADD2) set in operation S150.

In some embodiments, operation S140, operation S141, operation S150, operation S160, operation S161, operation S162, and operation S163 may be performed during the second power mode M2.

In operation S170, the electronic device 100 may change the power mode of the storage device 120 from the second power mode M2 to the first power mode M1, based on the acknowledge response ACK in operation S163. In an embodiment, operation S170 may include operation S171 and operation S172. In operation S171, the host device 110 may provide the first power supply voltage Vdd1 to the storage device 120. In operation S172, the host device 110 may provide the second power supply voltage Vdd2 to the storage device 120.

In operation S180, the storage device 120 may change the input address of the internal memory device of the storage device 120 from the second address ADD2 to the first address ADD1, based on the first power supply voltage Vdd1 being again supplied. That is, after the power mode is changed to the first power mode M1, the storage device 120 may restore the input address of the internal memory device of the storage device 120 to the first address ADD1 being the default address. In some embodiments, operation S180 may be performed during the first power mode M1.

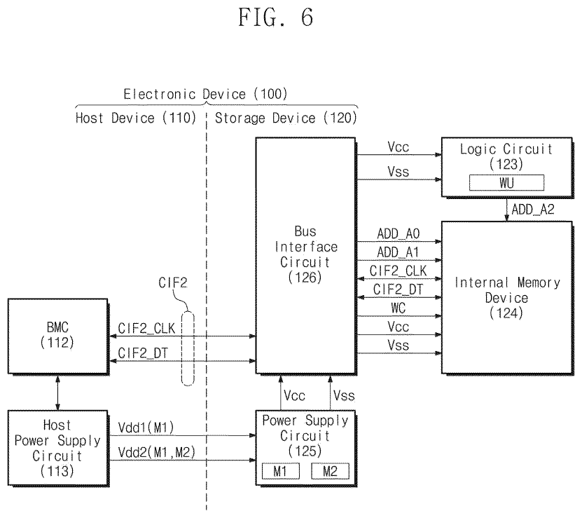

FIG. 6 is a block diagram of an electronic device according to some embodiments. Referring to FIG. 6, an electronic device 100 may include a host device 110 and a storage device 120. The host device 110 may include the BMC112 and the power host supply circuit 113. The storage device 120 may include the logic circuit 123, the internal memory device 124, the power supply circuit 125, and a bus interface circuit 126.

The BMC 112 may communicate with the bus interface circuit 126 through the second communication interface circuit CIF2. The second communication interface circuit CIF2 may be used to transmit a data signal CIF2_DT and a clock signal CIF2_CLK. The data signal CIF2_DT may indicate information to be stored in the internal memory device 124 or may indicate information obtained from the internal memory device 124. The clock signal CIF2_CLK which is a periodically toggling signal may be used to determine bit values of the data signal CIF2_DT. For example, in an embodiment, the data signal CIF2_DT may be a SM Bus data signal. The clock signal CIF2_CLK may be a SM Bus clock signal.

Under control of the BMC 112, the host power supply circuit 113 may independently provide the first power supply voltage Vdd1 and the second power supply circuit Vdd2 to the power supply circuit 125 of the storage device 120. The first power supply voltage Vdd1 may be used in the first power mode M1. The second power supply voltage Vdd2 may be used in the first power mode M1 and the second power mode M2.

The power supply circuit 125 may independently receive the first power supply voltage Vdd1 and the second power supply circuit Vdd2 from the host power supply circuit 113 of the host device 110. The power supply circuit 125 may support the first power mode M1 and the second power mode M2. During the second power mode M2, the power supply circuit 125 may provide an internal power supply voltage Vcc and a ground voltage Vss to the bus interface circuit 126 based on the second power supply voltage Vdd2.

The bus interface circuit 126 may provide a power and a signal to components (e.g., the logic circuit 123 and the internal memory device 124) activated during the second power mode M2. The bus interface circuit 126 may communicate with the BMC 112 through the second communication interface circuit CIF2.

The bus interface circuit 126 may receive the internal power supply voltage Vcc and the ground voltage Vss from the power supply circuit 125. The bus interface circuit 126 may provide the internal power supply voltage Vcc and the ground voltage Vss to the logic circuit 123. The bus interface circuit 126 may provide the internal power supply voltage Vcc and the ground voltage V ss to the internal memory device 124.

The bus interface circuit 126 may receive the data signal CIF2_DT and the clock signal CIF2_CLK from the internal memory device 124 and may provide the data signal CIF2_DT and the clock signal CIF2_CLK to the BMC 112 through the second communication interface circuit CIF2. The bus interface circuit 126 may receive the data signal CIF2_DT and the clock signal CIF2_CLK from the BMC 112 through the second communication interface circuit CIF2 and may provide the data signal CIF2_DT and the clock signal CIF2_CLK to the internal memory device 124.

The bus interface circuit 126 may provide address bit signals ADD_A0 and ADD_A1 to the internal memory device 124. The address bit signals ADD_A0 and ADD_A1 may be used to set a portion of the input address of the internal memory device 124. The bus interface circuit 126 may provide a write control signal WC to the internal memory device 124.

The write control signal WC may be used to control an operation of the internal memory device 124.

The logic circuit 123 may receive the internal power supply voltage Vcc and the ground voltage Vss from the bus interface circuit 126. The logic circuit 123 may manage the wake-up event WU. The logic circuit 123 may provide an address bit signal ADD_A2 to the internal memory device 124. The address bit signal ADD_A2 may be used to set a portion of the input address of the internal memory device 124.

The logic circuit 123 may provide the address bit signal ADD_A2 having a first voltage level (e.g., the logic low level) to the internal memory device 124 before the wake-up event WU is triggered. The logic circuit 123 may provide the address bit signal ADD_A2 having a second voltage level (e.g., the logic high level) to the internal memory device 124 in response to that the wake-up event WU is triggered. That is, the logic circuit 123 may change the input address of the internal memory device 124 based on the wake-up event WU.

The internal memory device 124 may receive the address bit signals ADD_A0 and ADD_A1, the clock signal CIF2_CLK, the data signal CIF2_DT, the write control signal WC, the internal power supply voltage Vcc, and the ground voltage Vss from the bus interface circuit 126. The internal memory device 124 may receive the address bit signal ADD_A2 from the logic circuit 123.

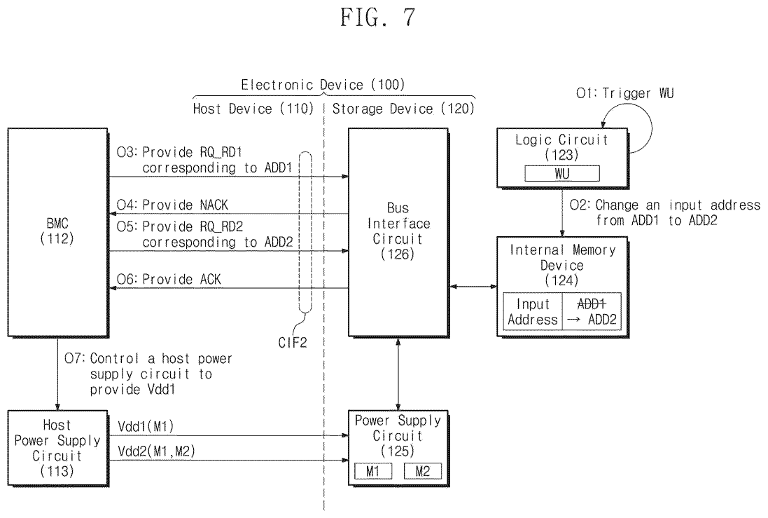

FIG. 7 is a diagram describing a method of operating an electronic device according to some embodiments. Referring to FIG. 7, the electronic device 100 may include the host device 110 and the storage device 120. The host device 110 may include the BMC 112 and the power host supply circuit 113. The storage device 120 may include the logic circuit 123, the internal memory device 124, the power supply circuit 125, and the bus interface circuit 126.

Below, a method of operating the electronic device 100 will be described in detail.

In a first operation O1, the logic circuit 123 may trigger the wake-up event WU. For example, the storage device 120 may operate in the second power mode M2. To change the power mode from the second power mode M2 to the first power mode M1, the logic circuit 123 may trigger the wake-up event WU.

In a second operation O2, the logic circuit 123 may change the input address of the internal memory device 124 from the first address ADD1 to the second address ADD2. The first address ADD1 may be a default address of the internal memory device 124. That is, the logic circuit 123 may set the input address of the internal memory device 124 to the second address ADD2. That the input address is set to the second address ADD2 may indicate the intention for the storage device 120 to exit the second power mode M2.

In a third operation O3, the BMC 112 may provide the first read request RQ_RD1 corresponding to the first address ADD1 to the internal memory device 124 through the bus interface circuit 126. The first read request RQ_RD1 may indicate an operation for obtaining FRU information or VPD information of the internal memory device 124 during the second power mode M2.

In a fourth operation O4, the internal memory device 124 may provide the negative acknowledge response NACK to the BMC 112 through the bus interface circuit 126 in response to the first address ADD1 corresponding to the first read request RQ_RD1 not coinciding with the set input address (i.e., the second address ADD2). In an embodiment, the negative acknowledgment response NACK may include information corresponding to the second address ADD2.

In a fifth operation O5, the BMC 112 may provide the second read request RQ_RD2 corresponding to the second address ADD2 to the internal memory device 124 through the bus interface circuit 126, based on the negative acknowledge response NACK. The second read request RQ_RD2 may indicate an operation for detecting the intention for the storage device 120 to exit the second power mode M2.

In a sixth operation O6, the internal memory device 124 may provide the positive acknowledge response ACK to the BMC 112 through the bus interface circuit 126 in response to the second address ADD2 corresponding to the second read request RQ_RD2 coinciding with the set input address (i.e., the second address ADD2).

In a seventh operation O7, the BMC 112 may control the host power supply circuit 113 based on the acknowledge response ACK such that the first power supply voltage Vdd1 is provided to the power supply circuit 125 of the storage device 120. The power supply circuit 125 may change the power mode from the second power mode M2 to the first power mode M1, based on the first power supply voltage Vdd1.

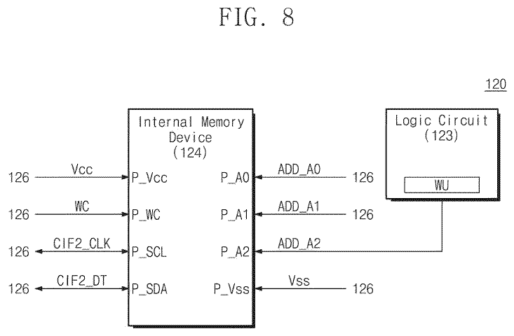

FIG. 8 is a block diagram of a storage device according to some embodiments. Referring to FIGS. 6 and 8, the storage device 120 may include the logic circuit 123, the internal memory device 124, and the bus interface circuit 126. The logic circuit 123 may manage the wake-up event WU.

In an embodiment, the internal memory device 124 may include a power port P_Vcc, a write control port P_WC, a clock port P_SCL, a data port P_SDA, an address port P_A0, an address port P_A1, an address port P_A2, and a ground port P_Vss.

The power port P_Vcc may receive the internal power supply voltage Vcc from the bus interface circuit 126. The internal power supply voltage Vcc may be based on the second power supply voltage Vdd2.

The write control port P_WC may receive the write control signal WC from the bus interface circuit 126.

The clock port P_SCL may be electrically connected to the bus interface circuit 126. The clock port P_SCL may exchange the clock signal CIF2_CLK with the BMC 112 of the host device 110 in both directions through the bus interface circuit 126.

The data port P_SDA may be electrically connected to the bus interface circuit 126. The data port P_SDA may exchange the data signal CIF2_DT with the BMC 112 of the host device 110 in both directions through the bus interface circuit 126.

The address port P_A0 may receive the address bit signal ADD_A0 from the bus interface circuit 126. The address bit signal ADD_A0 may set a first bit among bits corresponding to the input address of the internal memory device 124.

The address port P_A1 may receive the address bit signal ADD_A1 from the bus interface circuit 126. The address bit signal ADD_A1 may set a second bit among the bits corresponding to the input address of the internal memory device 124.

The address port P_A2 may be electrically connected to the logic circuit 123. The address port P_A2 may receive the address bit signal ADD_A2 from the logic circuit 123. The address bit signal ADD_A2 may set a third bit among the bits corresponding to the input address of the internal memory device 124.

When the address bit signal ADD_A2 has a first voltage level (e.g., the logic low level), the input address of the internal memory device 124 may be set to the first address ADD1. When the address bit signal ADD_A2 has a second voltage level (e.g., the logic high level), the input address of the internal memory device 124 may be set to the second address ADD2.

The ground port P_Vss may receive the ground voltage Vss from the bus interface circuit 126.

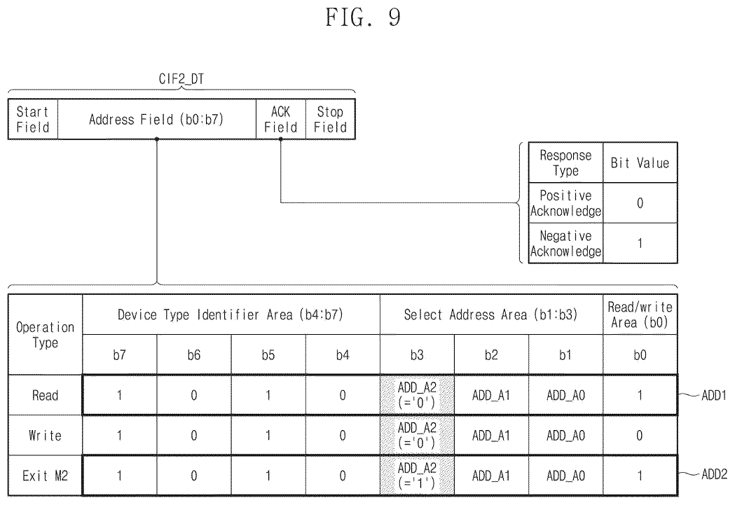

FIG. 9 is a diagram describing a data signal according to some embodiments. Referring to FIGS. 8 and 9, the data signal CIF2_DT may include a start field, an address field, an acknowledge (ACK) field, and a stop field. The start field may indicate a transmission start of the data signal CIF2_DT. The stop field may indicate a transmission end of the data signal CIF2_DT.

The address field may indicate an input address. The address field may include 8 bits b0 to b7. In detail, the address field may include bits b4 to b7 of a device type identifier area, bits b1 to b3 of a select address area, and a bit b0 of a read/write area.

The bit b0 of the read/write area may indicate an operation type. When the bit b0 of the read/write area indicates a first bit value (e.g., “1” or the logic high level), the data signal CIF2_DT may indicate the read operation or the exit intention of the second power mode M2. When the bit b0 of the read/write area indicates a second bit value (e.g., “0” or the logic low level), the data signal CIF2_DT may indicate the write operation.

The bits b1 to b3 of the select address area may correspond to the address bit signals ADD_A0 to ADD_A2. The address bit signals ADD_A0 and ADD_A1 may be uniquely assigned to the internal memory device 124. The address bit signal ADD_A2 may be controlled by the logic circuit 123. When the address bit signal ADD_A2 corresponds to the second bit value (e.g., “0” or the logic low level), the data signal CIF2_DT may indicate the exit intention of the second power mode M2. When the address bit signal ADD_A2 corresponds to the first bit value (e.g., “1” or the logic high level), the data signal CIF2_DT may indicate the read operation or the write operation.

The bits b4 to b7 of the device type identifier area may indicate a device type. For example, the bits b4 to b7 of the device type identifier area may be uniquely assigned to a storage device including the internal memory device 124.

In some embodiments, when the bit b3 among the bits b0 to b7 of the address field indicates the second bit value (e.g., “0” or the logic low level) and the bit b0 indicates the first bit value (e.g., “1” or the logic high level), the address field may indicate the first address

ADD1. The first address ADD1 may correspond to the read operation of the internal memory device 124.

In some embodiments, when the bit b3 among the bits b0 to b7 of the address field indicates the first bit value (e.g., “1” or the logic high level) and the bit b0 indicates the first bit value (e.g., “1” or the logic high level), the address field may indicate the second address ADD2. The second address ADD2 may indicate the intention to exist the second power mode M2.

The acknowledge field may have a 1-bit size. When the acknowledge field has the second bit value (e.g., “0” or the logic low level), a response type of the acknowledge field may indicate “acknowledge” (i.e., a positive acknowledge). When the acknowledge field has the first bit value (e.g., “1” or the logic high level), a response type of the acknowledge field may indicate “negative acknowledge”.

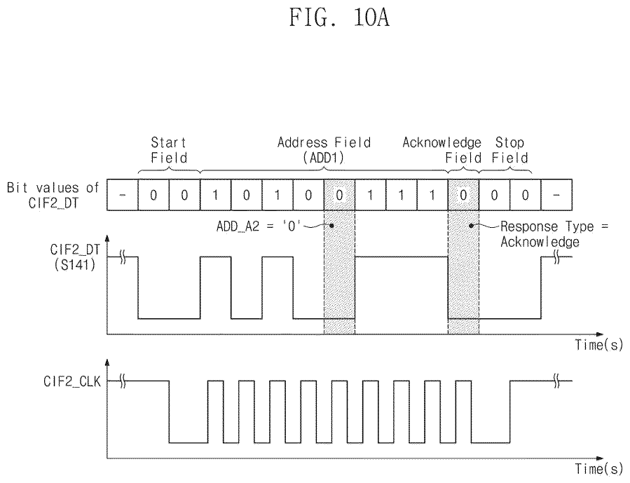

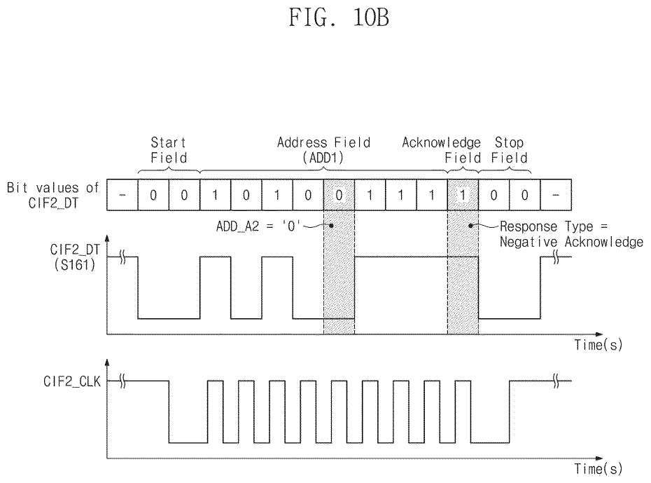

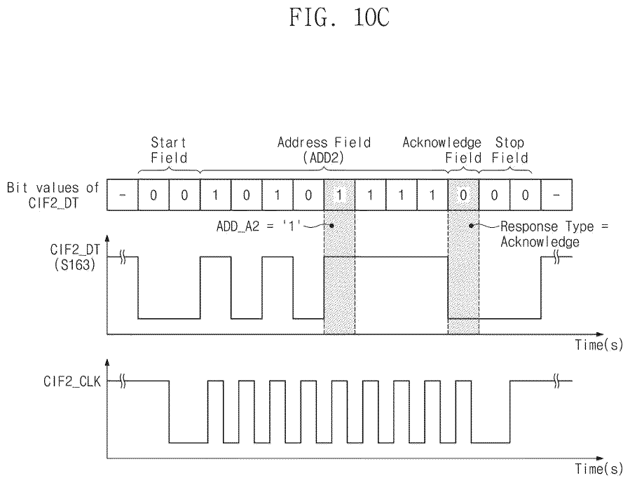

FIG. 10A is a diagram describing a data signal and a clock signal according to some embodiments. The data signal CIF2_DT and the clock signal CIF2_CLK will be described with reference to FIG. 10A. The data signal CIF2_DT may correspond to the acknowledge response A CK provided in operation S141 of FIG. 5. In graphs of the data signal CIF2_DT and the clock signal CIF2_CLK, the horizontal axis represents a time, and the vertical axis represents a logic level.

The bit values of the data signal CIF2_DT may constitute the start field, the address field, the acknowledge field, and the stop field.

The start field may indicate a transmission start of the data signal CIF2_DT from an internal memory device of a storage device to a host device.

The address field may indicate the first address ADD1. For example, a bit value corresponding to the address bit signal ADD_A2 from among the bit values of the address field may be “0”.

The acknowledge field may indicate whether a read request provided from the host device corresponds to an input address of the internal memory device. In the illustrated example in FIG. 10A, because the read request corresponds to the input address, a bit value of the acknowledge field may be “0”. A response type of the acknowledge field may indicate “acknowledge” (i.e., positive acknowledge). The description is given as the acknowledge field includes the acknowledge response.

The stop field may indicate a transmission end of the data signal CIF2_DT from the internal memory device of the storage device to the host device.

FIG. 10B is a diagram describing a data signal and a clock signal according to some embodiments. The data signal CIF2_DT and the clock signal CIF2_CLK will be described with reference to FIG. 10B. The data signal CIF2_DT may correspond to the negative acknowledge response NACK provided in operation S161 of FIG. 5. In graphs of the data signal CIF2_DT and the clock signal CIF2_CLK, the horizontal axis represents a time, and the vertical axis represents a logic level.

The bit values of the data signal CIF2_DT may constitute the start field, the address field, the acknowledge field, and the stop field.

The start field may indicate a transmission start of the data signal CIF2_DT from an internal memory device of a storage device to a host device.

The address field may indicate the first address ADD1. For example, a bit value corresponding to the address bit signal ADD_A2 from among the bit values of the address field may be “0”.

The acknowledge field may indicate whether a read request provided from the host device corresponds to an input address of the internal memory device. In the illustrated example of FIG. 10B, because the read request does not correspond to the input address, a bit value of the acknowledge field may be “1”. A response type of the acknowledge field may indicate “negative acknowledge”. The description is given as the acknowledge field includes the negative acknowledge response NACK.

The stop field may indicate a transmission end of the data signal CIF2_DT from the internal memory device of the storage device to the host device.

FIG. 10C is a diagram describing a data signal and a clock signal according to some embodiments. The data signal CIF2_DT and the clock signal CIF2_CLK will be described with reference to FIG. 10C. The data signal CIF2_DT may correspond to the acknowledge response ACK provided in operation S163 of FIG. 5. In graphs of the data signal CIF2_DT and the clock signal CIF2_CLK, the horizontal axis represents a time, and the vertical axis represents a logic level.

The bit values of the data signal CIF2_DT may constitute the start field, the address field, the acknowledge field, and the stop field.

The start field may indicate a transmission start of the data signal CIF2_DT from an internal memory device of a storage device to a host device.

The address field may indicate the second address ADD2. For example, a bit value corresponding to the address bit signal ADD_A2 from among the bit values of the address field may be “1”.

The acknowledge field may indicate whether a read request provided from the host device corresponds to an input address of the internal memory device. In the illustrated example of FIG. 10C, because the read request corresponds to the input address, a bit value of the acknowledge field may be “0”. A response type of the acknowledge field may indicate “acknowledge” (i.e., a positive acknowledge). The description is given as the acknowledge field includes the acknowledge response ACK.

The stop field may indicate a transmission end of the data signal CIF2_DT from the internal memory device of the storage device to the host device.

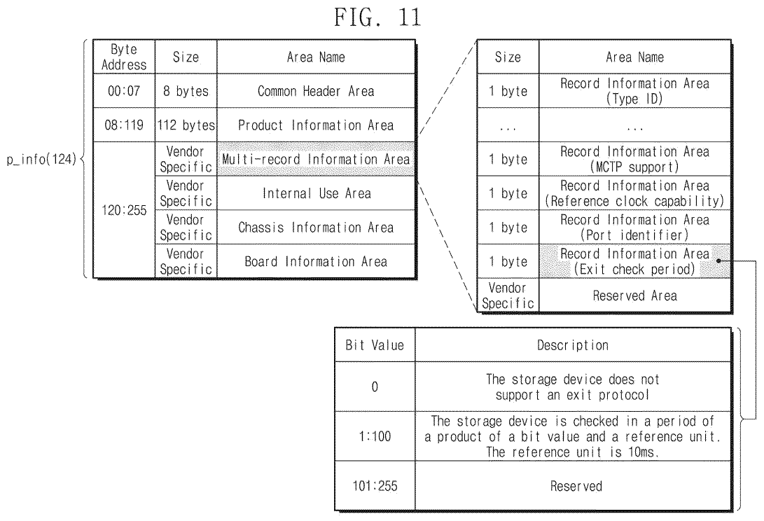

FIG. 11 is a diagram describing period information according to some embodiments. Referring to FIG. 11, the internal memory device 124 may store the period information p_info. The period information p_info may define a time period for performing the read operation of an internal memory device of a storage device by a host device. The period information p_info may be implemented as FRU information.

The period information p_info may include a common header area, a product information area, a multi-record information area, an internal use area, a chassis information area, and a board information area. In some embodiments, the internal use area, the chassis information area, and the board information area may be omitted.

The multi-record information area may include a plurality of record information areas. For example, the plurality of record information areas may include type identification information Type ID, MCTP support information, reference clock capability information, port identifier information, etc.

According to some embodiments, the plurality of record information areas included in the multi-record information area may further include exit check period information. The exit check period information may define a time period at which the read operation of the internal memory device of the storage device is performed by the host device. That is, the multi-record information area may define a time period between two successive read requests issued by the host device.

The exit check period information may have a 1-byte size. One byte may correspond to 8 bits. That is, the exit check period information may indicate one of 256 bit values.

In some embodiments, when the bit value of the exit check period information is “0”, the storage device may not support a protocol for exiting a second power mode.

In some embodiments, when the bit value of the exit check period information is one of 1 to 100, the storage device may be checked in a period of a product of a bit value and a reference value. In an embodiment, the reference value may be 10 ms. For example, in an embodiment, when the bit value is “10”, the host device may perform the read operation of the internal memory device of the storage device in a period of 100 ms. That is, there may be 100 ms between two successive read requests issued by the host device.

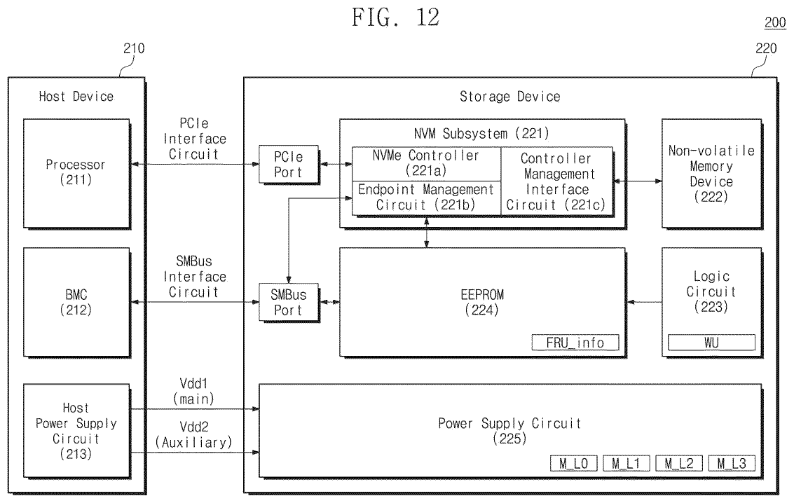

FIG. 12 is a block diagram of an electronic device according to some embodiments. Referring to FIG. 12, an electronic device 200 may include a host device 210 and a storage device 220.

The host device 210 may include a processor 211, a BMC 212, and a host power supply circuit 213. The processor 211 may communicate with the storage device 220 through the PCIe interface circuit. The BMC 212 may communicate with the storage device 220 through the SM Bus interface circuit. The host power supply circuit 213 may independently provide the first power supply voltage Vdd1 and the second power supply circuit Vdd2 to the storage device 220. The first power supply voltage Vdd1 may be referred to as a “main power supply voltage”. The second power supply voltage Vdd2 may be referred to as an “auxiliary power supply voltage”.

The storage device 220 may include a non-volatile memory (NVM) subsystem

221, a non-volatile memory device 222, a logic circuit 223, an EEPROM 224, a power supply circuit 225, a PCIe port, and an SM Bus port.

The NVM subsystem 221 may include a non-volatile memory express (NVMe) controller 221a, an endpoint management circuit 221b, and a controller management interface circuit 221c. The NVMe controller 221a may communicate with the processor 211 through the PCIe port. The endpoint management circuit 221b may communicate with the BMC 212 through the SM Bus port and may access the EEPROM 224. The controller management interface circuit 221c may provide an interface between the non-volatile memory device 222 and the NV Me controller 221a.

The non-volatile memory device 222 may store data under control of the NVM subsysteM221.

The logic circuit 223 may manage the wake-up event WU. The logic circuit 223 may trigger the wake-up event WU and may change an input address of the EEPROM 224 in response to that the wake-up event WU is triggered.

The EEPROM 224 may store FRU information FRU_info. The EEPROM 224 may communicate with the BMC 212 through the SM Bus port. The EEPROM 224 may be accessed by the endpoint management circuit 221b. The FRU information FRU_info may include period information defining a time period for performing the read operation by the BMC 212.

The power supply circuit 225 may receive the first power supply voltage Vdd1 and the second power supply circuit Vdd2 from the host power supply circuit 213. In an embodiment, the power supply circuit 225 may support power modes M_L0, M_L1, M_L2, and ML3.

The power mode M_L0 may correspond to an L0 link state defined by the PCIe standard. During the power mode M_L0, the storage device 220 may operate in the active state, based on the first and second power supply voltages Vdd1 and Vdd2. The power mode M_L0 may be referred to as a “normal mode”.

The power mode M_L1 may correspond to an L1 link state defined by the PCIe standard. During the power mode M_L1, the storage device 220 may operate in an idle state, based on the first and second power supply voltages Vdd1 and Vdd2.

The power mode M_L2 may correspond to an L2 link state defined by the PCIe standard. During the power mode M _L2, the storage device 220 may operate in the sleep state, based on the second power supply voltage Vdd2. In an embodiment, during the power mode M_L2, the storage device 220 may operate in the sleep state, based on only the second power supply voltage Vdd2. During the power mode M_L2, the logic circuit 223 and the EEPROM 224 may be activated. The second power mode M_L2 may be referred to as a “low power mode” or an “extreme low power mode”.

The power mode M_L3 may correspond to an L3 link state defined by the PCIe standard. During the power mode M_L3, the storage device 220 may not receive the first and second power supply voltages Vdd1 and Vdd2. The storage device 220 may be referred to as being in an off state during the power mode M_L3.

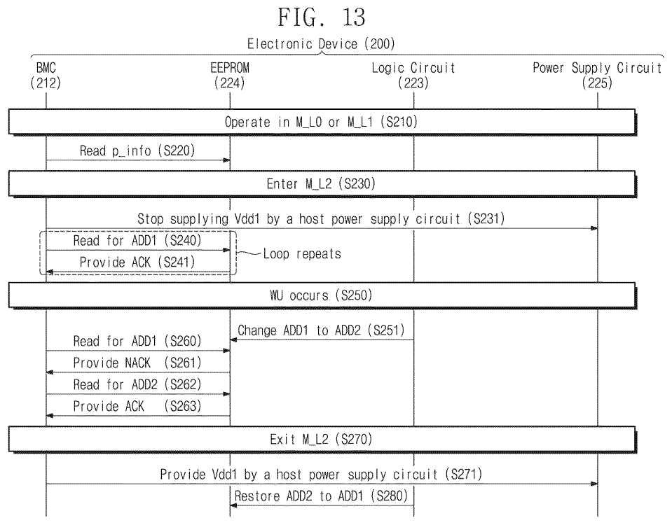

FIG. 13 is a flowchart describing a method of operating an electronic device according to some embodiments. Referring to FIGS. 12 and 13, the electronic device 200 may include the BMC 212, the logic circuit 223, the EEPROM 224, and the power supply circuit 225.

In operation S210, the electronic device 200 may operate in the power mode M_L0 or the power mode M_L1. For example, the storage device 220 of the electronic device 200 may be driven by the first and second power supply voltages Vdd1 and Vdd2.

In operation S220, the BMC 212 may read the period information p_info stored in the EEPROM 224. The period information p_info may be stored in the EEPROM 224 as the FRU information FRU_info.

In operation S230, the electronic device 200 may enter the power mode M_L2. For example, in an embodiment, the storage device 220 of the electronic device 200 may operate in the busy state for the change from the power mode M_L0 or M_L1 to the power mode M_L2.

In operation S231, the BMC 212 may control the host power supply circuit 213 to stop the first power supply voltage Vdd1 from being provided to the power supply circuit 225 of the storage device 220. Afterwards, the storage device 220 may be driven by the second power voltages Vdd2.

In operation S240, the BMC 212 may perform the read operation on the first address ADD1. In operation S241, the EEPROM 224 may provide the positive acknowledge response ACK to the BMC 212. A loop corresponding to operation S240 and operation S241 may be repeated depending on the time period defined by the period information p_info.

In operation S250, the wake-up event WU may occur. For example, the logic circuit 223 may trigger the wake-up event WU.

In operation S251, the logic circuit 223 may change the input address of the EEPROM 224 from the first address ADD1 to the second address ADD2.

In operation S260, the BMC 212 may perform the read operation on the first address ADD1. In operation S261, the EEPROM 224 may provide the negative acknowledge response NACK to the BMC 212. In operation S262, the BMC 212 may perform the read operation on the second address ADD2. In operation S263, the EEPROM 224 may provide the positive acknowledge response ACK to the BMC 212.

In operation S270, the electronic device 200 may exit the power mode M_L2. For example, in an embodiment, the storage device 220 of the electronic device 200 may operate in the busy state for the change from the power mode M_L2 to the power mode M_L0 or M_L1.

In operation S271, the BM C 212 may control the host power supply circuit 213 to supply the first power supply voltage Vdd1 to the power supply circuit 225 of the storage device 220. Afterwards, the storage device 220 may be driven by the first and second power supply voltages Vdd1 and Vdd2.

In operation S280, the logic circuit 223 may restore the input address of the EEPROM 224 from the second address ADD2 to the first address ADD1.

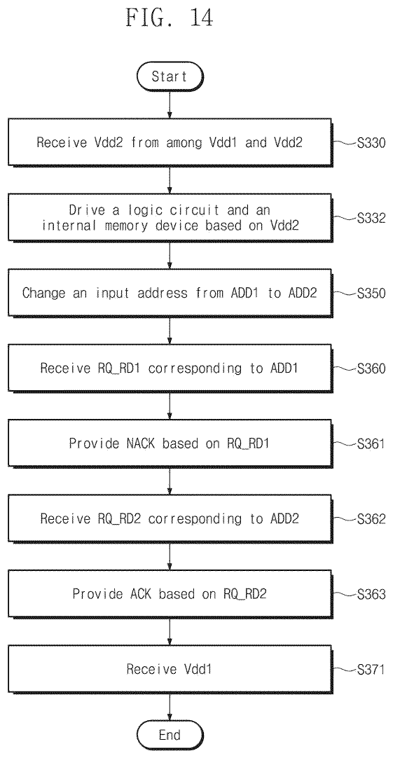

FIG. 14 is a flowchart describing a method of operating a storage device according to some embodiments. A storage device may communicate with a host device. The storage device may include a logic circuit and an internal memory device.

In operation S330, the storage device may receive the second power supply voltage Vdd2 from among the first power supply voltage Vdd1 and the second power supply voltage Vdd2 from the host device. That is, the storage device may not receive the first power supply voltage Vdd1 from the host device.

In operation S332, the storage device may drive the logic circuit and the internal memory device of the storage device based on the second power supply voltage Vdd2.

In operation S350, the logic circuit may change an input address of the internal memory device from the first address ADD1 to the second address ADD2.

In operation S360, the internal memory device may receive the first read request RQ_RD1 corresponding to the first address ADD1 from the host device.

In operation S361, the internal memory device may provide the negative acknowledge response NACK to the host device based on the first read request RQ_RD1.

In operation S362, the internal memory device may receive the second read request RQ_RD2 corresponding to the second address ADD2 from the host device.

In operation S363, the internal memory device may provide the positive acknowledge response ACK to the host device based on the second read request RQ_RD2.

In operation S371, the storage device may receive the first power supply voltage Vdd1 from the host device.

According to various embodiments, a storage device changing an address, a method of operating the same, and a method of operating an electronic device including the same are provided.

A storage device which stably provides an exit intention of a low power mode to a host device by changing an input address of an internal memory device activated during the low power mode without a change of the design of the host device, a method of operating the same, and a method of operating an electronic device including the same are provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A method of operating a storage device, the method comprising:
receiving a second power supply voltage among a first power supply voltage and the second power supply voltage from a host device;
driving a logic circuit and an internal memory device of the storage device, based on the second power supply voltage;
changing, by the logic circuit, an input address of the internal memory device from a first address to a second address;
receiving, by the internal memory device, a first read request corresponding to the first address from the host device;
providing, by the internal memory device, a negative acknowledge response to the host device based on the first read request;
after providing the negative acknowledge response, receiving, by the internal memory device, a second read request corresponding to the second address from the host device;
providing, by the internal memory device, a positive acknowledge response to the host device based on the second read request; and
after providing the positive acknowledge response, receiving the first power supply voltage from the host device.

2. The method of claim 1, wherein changing the input address includes:
triggering, by the logic circuit, a wake-up event; and
changing, by the logic circuit, a voltage level to be applied to a target address port among a plurality of address ports of the internal memory device from a first voltage level to a second voltage level, based on the wake-up event that is triggered.

3. The method of claim 1, wherein providing the negative acknowledge response includes providing, by the internal memory device, a first data signal and a first clock signal to the host device in response to the first read request, and
wherein the first data signal includes:
a start field indicating a transmission start of the first data signal;
an address field indicating the first address;
an acknowledge field including the negative acknowledge response; and
a stop field indicating a transmission end of the first data signal.

4. The method of claim 1, wherein providing the positive acknowledge response includes providing, by the internal memory device, a second data signal and a second clock signal to the host device in response to the second read request, and
wherein the second data signal includes:
a start field indicating a transmission start of the second data signal;
an address field indicating the second address;
an acknowledge field including the positive acknowledge response; and
a stop field indicating a transmission end of the second data signal.

5. The method of claim 1, further comprising:
after receiving the first power supply voltage, changing, by the logic circuit, the input address of the internal memory device from the second address to the first address.

6. The method of claim 1, wherein the storage device is configured to support:
a first power mode in which both the first power supply voltage and the second power supply voltage are used; and
a second power mode in which only the second power supply voltage is used.

7. The method of claim 6, wherein the first power supply voltage is a main power supply voltage,
wherein the second power supply voltage is an auxiliary power supply voltage being a constant voltage,
wherein the first power mode corresponds to an L0 link state defined by a peripheral component interconnect express (PCIe) standard, and
wherein the second power mode corresponds to an L2 link state defined by the PCIe standard.

8. The method of claim 6, wherein changing the input address includes:
during the second power mode, changing, by the logic circuit, the input address of the internal memory device from the first address to the second address.

9. The method of claim 1, further comprising:
before changing the input address of the internal memory device from the first address to the second address, operating in a first power mode;
during the first power mode, receiving, by the internal memory device, a third read request corresponding to period information from the host device; and
during the first power mode, providing, by the internal memory device, the period information to the host device.

10. The method of claim 9, wherein the period information includes field replaceable unit (FRU) information including a common header area, a product information area, and a multi-record information area, and
wherein the multi-record information area includes a record information area defining a time period between the first read request and the second read request.

11. The method of claim 1, wherein the internal memory device includes:
a power port configured to receive an internal power supply voltage which is based on the second power supply voltage;
a ground port configured to receive a ground voltage;
a write control port configured to receive a write control signal;
a clock port configured to communicate with the host device;
a data port configured to communicate with the host device;
a first address port configured to receive a first address bit signal;
a second address port configured to receive a second address bit signal; and
a target address port electrically connected to the logic circuit.

12. The method of claim 1, wherein the internal memory device includes an electrically erasable programmable read only memory (EEPROM).

13. The method of claim 1, wherein the storage device is configured to:
communicate with a processor of the host device through a PCIe interface circuit, based on the first power supply voltage; and
communicate with a baseboard management controller (BMC) of the host device through a system management bus (SM Bus) interface circuit, based on the second power supply voltage.

14. The method of claim 13, wherein the storage device performs communication of the first read request, the negative acknowledge response, the second read request, and the positive acknowledge response through the SM Bus interface circuit.

15. A storage device comprising:
a logic circuit;
an internal memory device; and
a power supply circuit configured to:
independently receive a first power supply voltage and a second power supply voltage from a host device,
support a first power mode in which both the first power supply voltage and the second power supply voltage are used,
support a second power mode in which only the second power supply voltage is used, and
drive the logic circuit and the internal memory device, based on the second power supply voltage,
wherein the logic circuit is configured to:
trigger a wake-up event for exiting the second power mode; and
change an input address of the internal memory device from a first address to a second address based on the wake-up event that is triggered, and
wherein the internal memory device is configured to:
receive a read request from the host device;
provide a positive acknowledge response to the host device in response to an address that corresponds to the read request coinciding with the input address; and
provide a negative acknowledge response to the host device in response to the address that corresponds to the read request not coinciding with the input address.

16. The storage device of claim 15, further comprising a bus interface circuit configured to:
receive the read request from the host device through a system management bus (SM Bus) interface circuit;
provide the read request to the internal memory device;
receive the positive acknowledge response or the negative acknowledge response from the internal memory device; and
provide the positive acknowledge response or the negative acknowledge response to the host device through the SM Bus interface circuit.

17. The storage device of claim 16, wherein the internal memory device includes:
a power port configured to receive an internal power supply voltage, which is based on the second power supply voltage, from the bus interface circuit;
a ground port configured to receive a ground voltage from the bus interface circuit;
a write control port configured to receive a write control signal from the bus interface circuit;
a clock port electrically connected to the bus interface circuit;
a data port electrically connected to the bus interface circuit;
a first address port configured to receive a first address bit signal from the bus interface circuit;
a second address port configured to receive a second address bit signal from the bus interface circuit; and
a target address port configured to receive a first voltage level corresponding to the first address or a second voltage level corresponding to the second address from the logic circuit.

18. A method of operating an electronic device which includes a host device and a storage device, the method comprising:
providing, by the host device, a second power supply voltage among a first power supply voltage and the second power supply voltage to the storage device;
driving, by the storage device, a logic circuit and an internal memory device of the storage device based on the second power supply voltage;
changing, by the logic circuit, an input address of the internal memory device from a first address to a second address;
providing, by the host device, a first read request corresponding to the first address to the internal memory device;
providing, by the internal memory device, a negative acknowledge response to the host device based on the first read request;
providing, by the host device, a second read request corresponding to the second address to the internal memory device, based on the negative acknowledge response;
providing, by the internal memory device, a positive acknowledge response to the host device based on the second read request; and
providing, by the host device, the first power supply voltage to the storage device based on the positive acknowledge response.

19. The method of claim 18, wherein changing the input address includes:
triggering, by the logic circuit, a wake-up event; and
changing, by the logic circuit, a voltage level to be applied to a target address port among a plurality of address ports of the internal memory device from a first voltage level to a second voltage level, based on the wake-up event that is triggered.

20. The method of claim 18, further comprising:
after receiving the first power supply voltage, changing, by the logic circuit, the input address of the internal memory device from the second address to the first address.
